(19) United States
(12) Patent Application Publication
(10) Pub. No.: US 2011/0275224 A1
(43) Pub. Date: Nov. 10, 2011

(54) METHOD FOR MANUFACTURING SILICON CARBIDE SUBSTRATE

(75) Inventors: Shin HARADA, Osaka-shi (JP); Makoto Sasaki, Itami-shi (JP); Hiroki Inoue, Itami-shi (JP)

(73) Assignee: SUMITOMO ELECTRIC INDUSTRIES, LTD., Osaka-shi (JP)

(21) Appl. No.: 13/100,527

(22) Filed: May 4, 2011

(30) Foreign Application Priority Data
May 6, 2010 (JP) 2010-106331

(51) Int. Cl. H01L 21/3105

(52) U.S. Cl. 438/759; 257/E21.241

(57) ABSTRACT

A material substrate is prepared which has a first surface and a second surface opposite to each other in a thickness direction and is made of silicon carbide. The material substrate is partially carbonized to divide the material substrate into a carbonized portion made of a material obtained by carbonizing silicon carbide, and a silicon carbide portion made of silicon carbide. This step of partially carbonizing the material substrate is performed to partially carbonize the second surface. In order to adjust a shape of the material substrate when viewed in a planar view, a portion of the material substrate is removed. This step of removing the portion of the material substrate includes the step of processing the carbonized portion. Accordingly, a silicon carbide substrate having a desired planar shape can be obtained readily.

### BACKGROUND OF THE INVENTION

1. Field of the Invention

The present invention relates to a method for manufacturing a silicon carbide substrate.

2. Description of the Background Art

A method for manufacturing a silicon carbide substrate is disclosed in, for example, U.S. Pat. No. 7,314,520. Utilization of such a silicon carbide substrate for manufacturing of semiconductor devices provides, for example, the following advantages over utilization of more general silicon substrates: the semiconductor devices have high reverse breakdown voltage, have low on-resistance, and can be operated even under a high temperature.

In order to manufacture semiconductor devices using a semiconductor substrate, the semiconductor substrate needs to have a predetermined planar shape. However, in view of material characteristics of silicon carbide, it is relatively difficult to adjust the planar shape of a silicon carbide substrate. For example, hardness of silicon carbide makes it difficult to adjust the planar shape of a silicon carbide substrate by means of a machining process.

### SUMMARY OF THE INVENTION

The present invention has been made in view of the above-described problem, and its object is to provide a method for manufacturing a silicon carbide substrate, so as to readily obtain a silicon carbide substrate having a desired planar shape.

A method for manufacturing a silicon carbide substrate in the present invention includes the following steps.

There is prepared a material substrate having first and second surfaces opposite to each other in a thickness direction and made of silicon carbide. The material substrate is partially carbonized to divide the material substrate into a carbonized portion and a silicon carbide portion, the carbonized portion being made of a material obtained by carbonizing silicon carbide, the silicon carbide portion being made of silicon carbide. The step of partially carbonizing the material substrate is performed to partially carbonize the second surface. Next, a portion of the material substrate is removed to adjust a shape of the material substrate when viewed in a planar view. The step of removing the portion of the material substrate includes the step of processing the carbonized portion. It should be noted that the “step of processing the carbonized portion” is not limited to a step acting even upon the inside of carbonized portion (for example, a step of cutting off the carbonized portion), and may be a step acting on an interface of the carbonized portion.

According to the present invention, at least a part of the process for removing the material substrate represents a process on the carbonized portion, which is made of the material obtained by carbonizing silicon carbide. The process on the carbonized portion can be readily performed as compared with a process on the portion made of silicon carbide. Accordingly, at least a part of the process for removing the portion of the material substrate can be performed more readily. Accordingly, a silicon carbide substrate having a desired planar shape can be obtained readily.

Preferably, the step of removing the portion of the material substrate includes the step of applying stress to the material substrate. Thus, the portion of the material substrate can be removed using such a simple method as application of stress.

Preferably, the step of processing the carbonized portion is performed by separating the carbonized portion from its interface with the silicon carbide portion by the stress. As such, the carbonized portion can be processed with smaller stress.

Preferably, the step of removing the portion of the material substrate includes the step of developing a crack, which is caused by separating the carbonized portion, to come into the silicon carbide portion. In this way, the silicon carbide portion can be processed in succession to the processing on the carbonized portion by the separation.

In the above-described method for manufacturing the silicon carbide substrate, the step of processing the carbonized portion includes the step of cutting off the carbonized portion by means of at least one of a machining process such as grinding or polishing, a laser process, and an electric discharge process.

Preferably, the step of partially carbonizing the material substrate includes the step of heating the material substrate to partially carbonize the material substrate. Accordingly, the step of carbonizing can be performed readily.

Preferably, the step of heating the material substrate includes the step of subjecting the material substrate to an atmosphere having a temperature of not less than 1800° C. and not more than 2500° C. By setting the temperature at 1800° C. or greater, the step of carbonizing can be performed more securely. Meanwhile, by setting the temperature at 2500° C. or smaller, the material substrate can be less damaged by the heating.

Preferably, the step of partially carbonizing the material substrate includes the step of evacuating an atmosphere surrounding the material substrate. This can facilitate development of the carbonization.

Preferably, a first protective film is formed on the first surface before the step of partially carbonizing the material substrate. Accordingly, the first surface can be prevented from being carbonized.

Preferably, the first protective film is made of a first material containing carbon as its main component. The first material may contain at least one of diamondlike carbon, carbon, a material obtained by carbonization of a resist, and a material obtained by carbonization of silicon carbide. Accordingly, the first protective film is improved in heat resistance, thus preventing carbonization of the first surface more securely.

Preferably, before the step of partially carbonizing the material substrate, there is formed a base portion connected to and partially covering the second surface of the material substrate and made of silicon carbide. Because this base portion is made of silicon carbide, the base portion is suitable to constitute a portion of the silicon carbide substrate. Further, the base portion serves as a mask partially covering the second surface, whereby only portion of the second surface can be carbonized.

Preferably, before the step of partially carbonizing the material substrate, a second protective film is formed on the base portion. Accordingly, the base portion can be prevented from being carbonized.

Preferably, the material substrate includes at least one single-crystal. Accordingly, a silicon carbide substrate having a single-crystal can be obtained.

Preferably, the at least one single-crystal includes a plurality of single-crystals located at different locations when viewed in a planar view. Accordingly, a silicon carbide substrate having a larger area can be obtained.

As apparent from the description above, according to the present invention, a silicon carbide substrate having a desired planar shape can be obtained readily.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a configuration of a silicon carbide substrate in a first embodiment of the present invention.

FIG. 2 is a plan view schematically showing a first step of a method for manufacturing the silicon carbide substrate in the first embodiment of the present invention.

FIG. 3 is a schematic cross sectional view taken along a line in FIG. 2.

FIG. 4 is a cross sectional view schematically showing a second step of the method for manufacturing the silicon carbide substrate in the first embodiment of the present invention.

FIG. 5 is a plan view schematically showing a third step of the method for manufacturing the silicon carbide substrate in the first embodiment of the present invention.

FIG. 6 is a schematic cross sectional view taken along a line VI-VI in FIG. 5.

FIG. 7 is a cross sectional view schematically showing a fourth step of the method for manufacturing the silicon carbide substrate in the first embodiment of the present invention.

FIG. 8 is a plan view schematically showing a fifth step of the method for manufacturing the silicon carbide substrate in the first embodiment of the present invention.

FIG. 9 is a schematic cross sectional view taken along a line IX-IX in FIG. 8.

FIG. 10 is a partial cross sectional view schematically showing a sixth step of the method for manufacturing the silicon carbide substrate in the first embodiment of the present invention.

FIGS. 11 and 12 are partial cross sectional views schematically showing first and second steps of a method for manufacturing a silicon carbide substrate in a second embodiment of the present invention.

FIG. 13 is a cross sectional view schematically showing a first step of a method for manufacturing a silicon carbide substrate in a third embodiment of the present invention.

FIG. 14 is a partial cross sectional view schematically showing a second step of the method for manufacturing the silicon carbide substrate in the third embodiment of the present invention as well as its variation.

FIG. 15 is a plan view schematically showing a configuration of a silicon carbide substrate in a fourth embodiment of the present invention.

FIG. 16 is a schematic cross sectional view taken along a line XVI-XVI in FIG. 15.

FIG. 17 is a plan view schematically showing a first step of a method for manufacturing the silicon carbide substrate in the fourth embodiment of the present invention.

FIG. 18 is a schematic cross sectional view taken along a line XVIII-XVIII in FIG. 17.

FIGS. 19-21 are cross sectional views schematically showing second to fourth steps of the method for manufacturing the silicon carbide substrate in the fourth embodiment of the present invention.

FIG. 22 is a partial cross sectional view schematically showing a fifth step of the method for manufacturing the silicon carbide substrate in the fourth embodiment of the present invention.

FIGS. 23 and 24 are partial cross sectional views schematically showing first and second steps of a method for manufacturing a silicon carbide substrate in a fifth embodiment of the present invention.

FIG. 25 is a cross sectional view schematically showing a first step of a method for manufacturing a silicon carbide substrate in a sixth embodiment of the present invention.

FIG. 26 is a partial cross sectional view schematically showing a second step of the method for manufacturing the silicon carbide substrate in the sixth embodiment of the present invention as well as its variation.

FIG. 27 is a plan view schematically showing a first step of a method for manufacturing a silicon carbide substrate in a seventh embodiment of the present invention.

FIG. 28 is a schematic cross sectional view taken along a line XXVIII-XXVIII in FIG. 27.

FIG. 29 is a cross sectional view schematically showing a second step of the method for manufacturing the silicon carbide substrate in the seventh embodiment of the present invention.

FIG. 30 is a partial cross sectional view schematically showing a configuration of a semiconductor device in an eighth embodiment of the present invention.

FIG. 31 is a schematic flowchart showing a method for manufacturing the semiconductor device in the eighth embodiment of the present invention.

FIGS. 32-36 are partial cross sectional views schematically showing first to fifth steps of the method for manufacturing the semiconductor device in the eighth embodiment of the present invention.

### DESCRIPTION OF THE PREFERRED EMBODIMENTS

The following describes embodiments of the present invention with reference to figures.

### First Embodiment

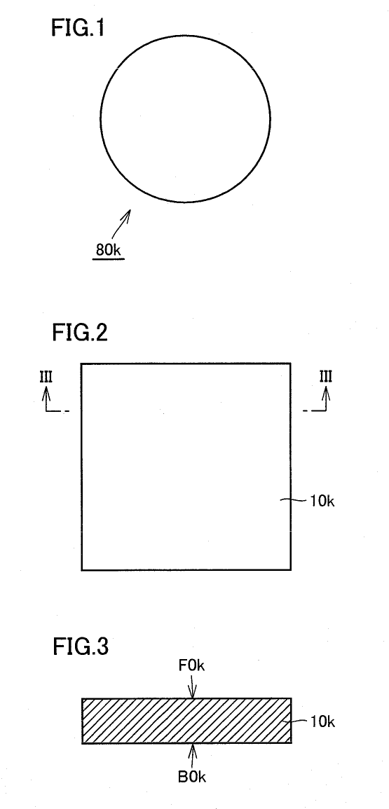

As shown in FIG. 1, a silicon carbide substrate 80k of the present embodiment has a predetermined shape (for example, a circular shape as shown in the figure) when viewed in a planar view. Further, silicon carbide substrate 80k is made of silicon carbide, and is preferably of single crystal. The following describes a method for manufacturing such a silicon carbide substrate 80k.

Referring to FIG. 2 and FIG. 3, a material substrate 10k made of silicon carbide is prepared. Material substrate 10k has first surface F0k and second surface B0k opposite to each other in the direction of thickness (vertical direction in FIG. 3). In the case where material substrate 10k is formed of single-crystal silicon carbide, material substrate 10k can be obtained by, for example, slicing an ingot fabricated using a so-called sublimation method.

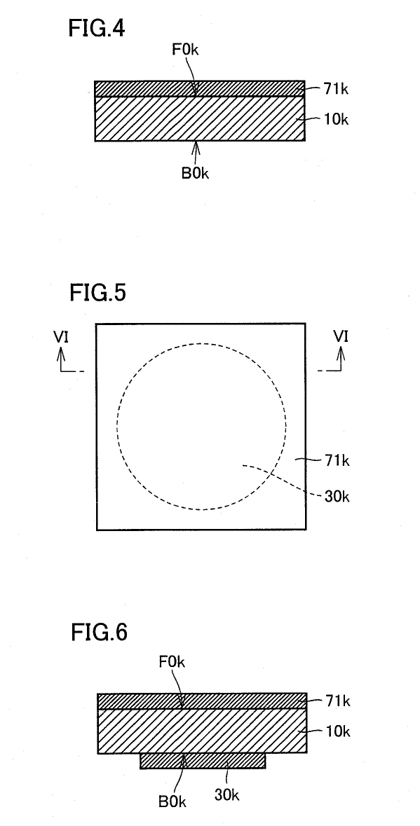

Referring to FIG. 4, a first protective film 71k is formed on first surface F0k of material substrate 10k. Preferably, first protective film 71k is made, of a material containing carbon as its main component. This material may contain at least one of diamondlike carbon, carbon, a material obtained by carbonization of a resist, and a material obtained by carbonization of silicon carbide. As the resist, a photoresist may be employed. In the case where this material is, for example, carbon, first protective film 71k can be formed by means of a sputtering method.

Referring to FIG. 5 and FIG. 6, a mask layer 30k is formed on second surface B0k of material substrate 10k so as to partially cover second surface B0k. The planar shape of mask layer 30k (a broken line in FIG. 5) corresponds to the planar shape of material substrate 10k. Mask layer 30k can be made of, for example, the same material as the material of first protective film 71k.

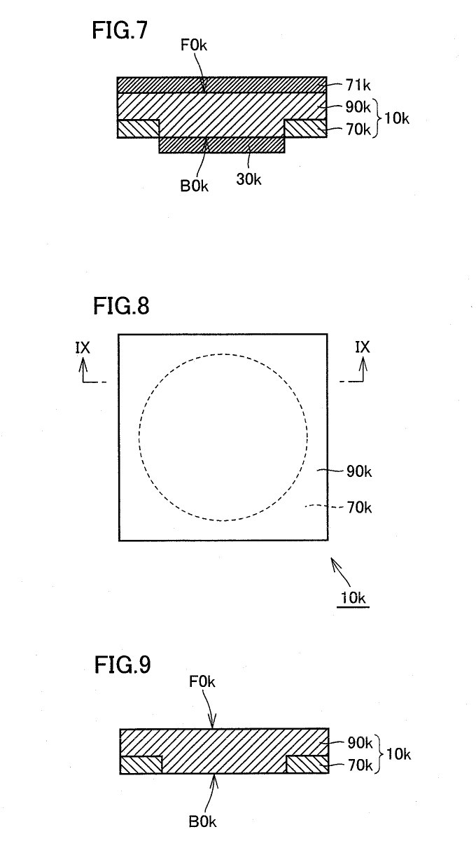

Referring to FIG. 7, material substrate 10k thus provided with first protective film 71k and mask layer 30k is heated, thereby carbonizing a part of material substrate 10k. Specifically, silicon atoms are desorbed from a portion not covered with mask layer 30k in second surface B0k of material substrate 10k, whereby a carbonized portion 70k is formed to extend from the portion up to a depth smaller than the thickness of material substrate 10k. As such, carbonized portion 70k is made of a material obtained by carbonizing silicon carbide, and is made of carbon if the carbonization develops sufficiently. A portion not carbonized in material substrate 10k is still made of silicon carbide. This portion will be referred to as “silicon carbide portion 90k”. Preferably, this carbonization is accomplished by subjecting material substrate 10k to an atmosphere having a temperature of not less than 1800° C. and not more than 2500° C. Further, this carbonization is performed while evacuating the atmosphere surrounding material substrate 10k. Then, first protective film 71k and mask layer 30k are removed by, for example, grinding or polishing.

Referring to FIG. 8 and FIG. 9, by the above-described step, material substrate 10k is divided into carbonized portion 70k and silicon carbide portion 90k. Further, second surface B0k is divided into a portion in which silicon carbide portion 90k is exposed in a shape corresponding to the planar shape of mask layer 30k; and a portion in which carbonized portion 70k is exposed and which is located outside the portion in which silicon carbide portion 90k is exposed.

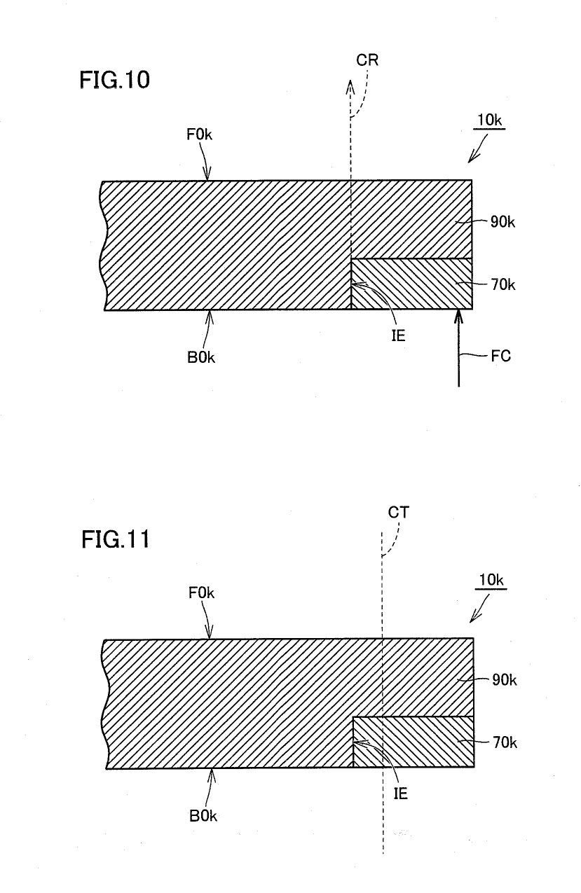

Referring to FIG. 10, as a result of the carbonization, an interface IE is formed between carbonized portion 70k and silicon carbide portion 90k, so as to extend from second surface B0k to come into material substrate 10k in the direction in which the carbonization has developed, i.e., substantially the direction of thickness (vertical direction in FIG. 10).

Then, in order to facilitate separation along interface IE, stress is applied to material substrate 10k. For example, force FC is applied to push carbonized portion 70k on second surface B0k while the portion of second surface B0k constituted by silicon carbide portion 90k in material substrate 10k (portion on the left side in FIG. 10) is fixed. This force FC causes stress in material substrate 10k, which results in separation along interface IE from a location on second surface B0k. In other words, a process is performed to separate carbonized portion 70k along its interface.

This separation causes a crack along interface IE. The crack develops to come into silicon carbide portion 90k, and finally reaches first surface F0k. In other words, the crack develops as indicated by a broken line arrow CR (FIG. 10). As a result, when viewed in a planar view, the portion provided with carbonized portion 70k in material substrate 10k (portion located at the right side with respect to broken line arrow CR in FIG. 10) is removed, while the other portion remains.

This remaining portion has a shape corresponding to that of mask layer 30k (FIG. 5) when viewed in a planar view, i.e., a shape corresponding to that of silicon carbide substrate 80k. Namely, by the steps described above, material substrate 10k (FIG. 2) is provided with a planar shape corresponding to that of silicon carbide substrate 80k.

Material substrate 10k thus newly provided with the planar shape is likely to have rough a side surface because the side surface is formed as a result of the development of the crack. Hence, the side surface may be cut, ground, or polished as required. In this way, silicon carbide substrate 80k is obtained.

It should be noted that for ease of illustration, in FIG. 5 and FIG. 8, the shape of material substrate 10k is illustrated as a square shape, but the shape of material substrate 10k may be any shape so long as it is larger than the planar shape of silicon carbide substrate 80k.

According to the present embodiment, the following processes are performed as the process for removing the portion of material substrate 10k (portion located at the right side with respect to broken line arrow CR in FIG. 10) in order to adjust the planar shape of material substrate 10k: the process on interface IE of carbonized portion 70k as indicated by broken line arrow CR (FIG. 10); and the process on the inside of silicon carbide portion 90k. The former process, i.e., the process for separation along interface IE, can be readily performed as compared with a process on silicon carbide, which has a high hardness. Thus, a part of the process of adjusting the planar shape of material substrate 10k can be done more readily. Accordingly, silicon carbide substrate 80k having a desired planar shape can be obtained readily.

The separation along interface IE (FIG. 10) can be done only by such a simple method as application of stress onto interface IE in material substrate 10k. Further, the crack resulting from the separation develops to come into silicon carbide portion 90k. In this way, a process of forming a crack at a desired location in silicon carbide portion 90k can be attained readily.

Further, carbonized portion 70k (FIG. 7) can be formed by a simple method such as heating of material substrate 10k. When temperature in the atmosphere upon the heating is set at 1800° C. or greater, the carbonization is done more securely. In addition, when the temperature is set at 2500° C. or smaller, material substrate 10k can be less damaged by the heating. By heating with the atmosphere being evacuated, silicon atoms desorbed from material substrate 10k are removed from the atmosphere, thereby facilitating further desorption of silicon atoms from material substrate 10k to the atmosphere. In other words, development of carbonization is facilitated, thereby efficiently manufacturing silicon carbide substrate 80k.

Further, first protective film 71k (FIG. 7) serves to prevent carbonization of first surface F0k. Preferably, first protective film 71k is made of a material containing carbon as its main component. This material may contain at least one of diamondlike carbon, carbon, a material obtained by carbonization of a resist, and a material obtained by carbonization of silicon carbide. Accordingly, first protective film 71k becomes a film stable even under a high temperature, thereby preventing carbonization of first surface F0k more securely. Note that it is not essential to form first protective film 71k. In the case where first protective film 71k is not formed, first surface F0k is carbonized up to a certain depth upon forming carbonized portion 70k, but the portion carbonized in first surface F0k can be removed by, for example, grinding or polishing.

### Second Embodiment

A silicon carbide substrate of the present embodiment has a configuration substantially the same as that in the first embodiment (FIG. 1). Further, early steps in a method for manufacturing the silicon carbide substrate of the present embodiment are the same as those in the method for manufacturing in the first embodiment (steps for obtaining the configuration of FIG. 9). The same or corresponding elements as those in the first embodiment are given the same reference characters and are not described repeatedly. The following describes later steps in the manufacturing method in the present embodiment.

Referring to FIG. 8, FIG. 9, and FIG. 11, when viewed in a planar view, most of the portion provided with carbonized portion 70k (portion located at an outer side relative to the broken line in FIG. 8) is removed. Namely, as indicated by broken line CT (FIG. 11), carbonized portion 70k and silicon carbide portion 90k are cut at a location located at an outer side relative to interface IE. This cutting-off is done by, for example, at least one of a machining process such as grinding or polishing, a laser process, and an electric discharge process.

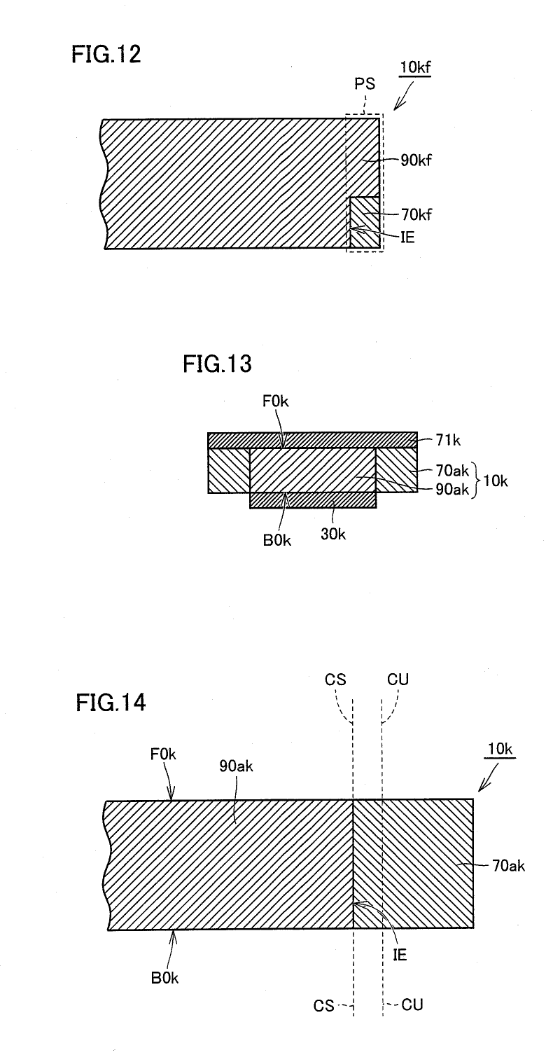

Further, referring to FIG. 12, most of carbonized portion 70k (FIG. 11) is removed by the cutting-off, although there is a remaining portion of carbonized portion 70k, i.e., a carbonized portion 70kf (FIG. 12). Then, a portion in which carbonized portion 70kf exists when viewed in a planar view, i.e., a portion PS (FIG. 12) having carbonized portion 70kf and a silicon carbide portion 90kf are removed by, for example, cutting, grinding, or polishing. Accordingly, silicon carbide substrate 80k (FIG. 1) is obtained.

According to the present embodiment, as shown in FIG. 11, a part of the process of cutting off material substrate 10k represents the process of cutting off carbonized portion 70k. Specifically, in the part of the process of cutting off material substrate 10k, the material obtained by carbonizing silicon carbide, rather than silicon carbide, is cut off. Such a process can be readily performed as compared with a process of cutting off silicon carbide. As such, the part of the process of cutting off material substrate 10k can be performed more readily. Accordingly, silicon carbide substrate 80k having a desired planar shape can be obtained readily.

### Third Embodiment

A silicon carbide substrate of the present embodiment has a configuration substantially the same as that in the first embodiment (FIG. 1). Further, early steps in a method for manufacturing the silicon carbide substrate of the present embodiment are the same as those in the method for manufacturing in the first embodiment (steps for obtaining the configuration of FIG. 7). The same or corresponding elements as those in the first embodiment are given the same reference characters and are not described repeatedly. The following describes later steps in the manufacturing method in the present embodiment.

Referring to FIG. 7, the carbonizing step is performed in a manner similar to that in the first embodiment, thereby forming carbonized portion 70k. In the present embodiment, the carbonization is developed further.

Referring to FIG. 13, by the above-described step, material substrate 10k is divided into a carbonized portion 70ak and a silicon carbide portion 90ak. Carbonized portion 70ak is formed to extend from second surface B0k to first surface F0k.

Referring to FIG. 14, as indicated by a broken line CS in the figure, separation is done along interface IE between carbonized portion 70ak and silicon carbide portion 90ak. This separation is attained by applying stress in the same manner as in the first embodiment. As a result of this separation, carbonized portion 70ak is removed. Thereafter, each side surface of 90ak (surface used to be interface IE) may be cut, ground, or polished. Accordingly, silicon carbide substrate 80k (FIG. 1) is obtained.

Instead of the separation along broken line CS (FIG. 14), it may be cut along a broken line CU (FIG. 14). This cutting may be performed using a method similar to that in the second embodiment. A remaining portion of carbonized portion 70ak (portion between broken line CU and interface IE in FIG. 14) is removed by, for example, cutting, grinding, or polishing.

Further, instead of first protective film 71k, a layer similar to mask layer 30k may be formed on first surface F0k. In this way, carbonization for formation of carbonized portion 70a develops not only from second surface B0k but also from first surface F0k, thereby forming carbonized portion 70ak more efficiently.

### Fourth Embodiment

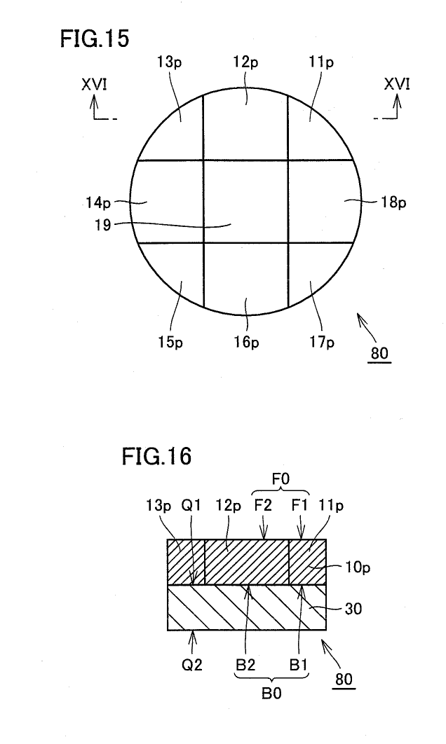

As shown in FIG. 15 and FIG. 16, a silicon carbide substrate 80 of the present embodiment has a base portion 30 and a single-crystal group 10p (FIG. 16).

Base portion 30 is formed of silicon carbide. Base portion 30 is a plate-like member having a circular shape. Specifically, base portion 30 has a first main surface Q1 and a second main surface Q2 opposite to each other. First main surface Q1 and second main surface Q2 have substantially the same circular shape.

Single-crystal group 10p is constituted by single-crystals 11p-18p and 19 each made of silicon carbide having a single-crystal structure. Further, those in single-crystal group 10p are disposed at different locations on first main surface Q1 of base portion 30 and are arranged in the form of a matrix, for example. Further, single-crystal group 10p substantially corresponds to the circular shape of main surface Q1. In other words, single-crystal group 10p as a whole has a circular shape substantially the same as that of first main surface Q1 when viewed in a planar view, and they are substantially overlapped with each other.

Single-crystal lip has a front-side surface F1 and a backside surface B1 opposite to each other. Likewise, single-crystal 12p has a front-side surface F2 and a backside surface B2 opposite to each other. Each of backside surfaces B1 and B2 is connected to base portion 30. Each of the other single-crystals included in single-crystal group 10p has a similar configuration. It should be noted that the front-side surface of single-crystal group 10p including front-side surfaces F1, F2, and the like (surface shown in FIG. 15) will be referred to as “first surface F0”, whereas the backside surface of single-crystal group 10p including backside surfaces B1, B2, and the like (surface opposite to the surface shown in FIG. 15) will be referred to as “second surface B0”.

The following describes a method for manufacturing silicon carbide substrate 80.

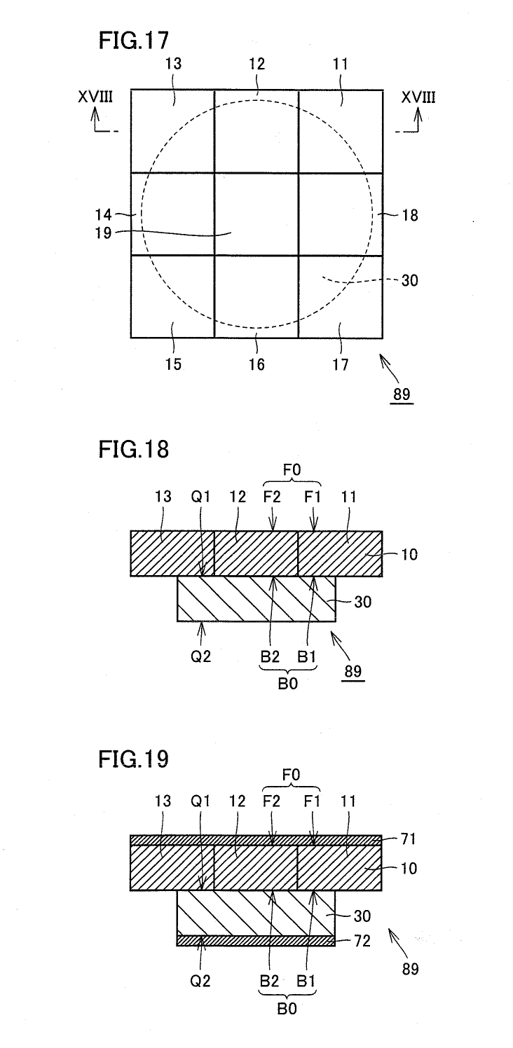

Referring to FIG. 17 and FIG. 18, a combined substrate 89 is prepared as a member for manufacturing of silicon carbide substrate 80 described above. It should be noted that a method for manufacturing combined substrate 89 will be described in a seventh embodiment.

Combined substrate 89 will be formed into silicon carbide substrate 80 by processing its shape. Combined substrate 89 has single-crystal group 10 (material substrate) and base portion 30. Single-crystal group 10 will be formed into the above-described single-crystal group 10p by removing a portion thereof to adjust the planar shape of single-crystal group 10. As such, when viewed in a planar view, single-crystal group 10 has a shape containing single-crystal group 10p therein (shape containing the circular shape of FIG. 15 therein). For example, single-crystal group 10 has outer edges constituted by a plurality of straight lines (outer edges forming a square constituted by four straight lines in FIG. 17). Further, single-crystal group 10 has first surface F0 (surface shown in FIG. 17) and second surface B0 (surface opposite to the surface shown in FIG. 17) opposite to each other in the direction of thickness, as with single-crystal group 10p.

For ease of illustration, in FIG. 17, single-crystals 11-19 (single-crystal group 10) each having a square shape are arranged in the form of a matrix and single-crystal group 10 as a whole also has a square shape. However, the entire single-crystal group 10 and each single-crystal in single-crystal group 10 may be in any form so long as the entire shape of single-crystal group 10 is larger than the circular shape of base portion 30.

Single-crystal group 10 has single-crystals 11-19. Single-crystals 11-18 will be formed into single-crystals 11p-18p (FIG. 15) respectively by adjusting their planar shapes. In other words, single-crystals 11-18 are substantially the same as single-crystal 11p-18p, apart from their planar shapes. It should be noted that the planar shape of single-crystal 19 is maintained and unchanged between before and after the adjustment of the planar shapes.

Referring to FIG. 19, first protective film 71 is formed on first surface F0 of single-crystal group 10. Preferably, first protective film 71 is made of a material containing carbon as its main component. This material is, for example, the same one as first protective film 71k of the first embodiment. Further, second protective film 72 is formed on second main surface Q2 of base portion 30. Second protective film 72 can be formed of the same material as that of first protective film 71 described above.

Then, combined substrate 89 thus provided with first protective film 71 and second protective film 72 is heated. Preferably, this heating is performed by subjecting combined substrate 89 to an atmosphere having a temperature of not less than 1800° C. and not more than 2500° C., while evacuating the atmosphere surrounding combined substrate 89.

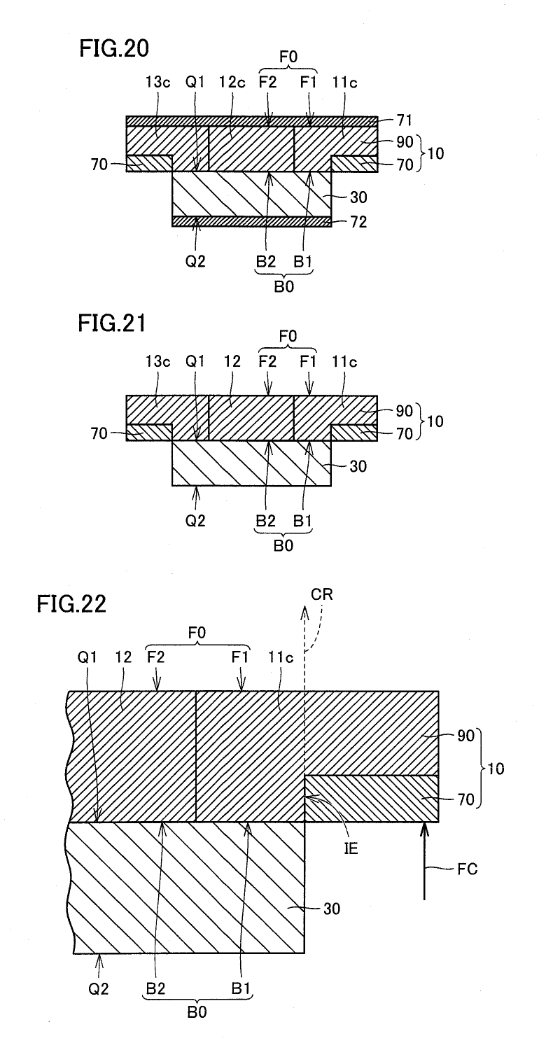

Referring to FIG. 20, the heating results in carbonization of a part of single-crystal group 10. Specifically, silicon atoms are desorbed from a portion not covered with base portion 30 in second surface B0 of single-crystal group 10, whereby a carbonized portion 70 is formed in single-crystal group 10 to extend from the portion up to a depth smaller than the thickness of single-crystal group 10. As such, carbonized portion 70 is made of a material obtained by carbonizing silicon carbide. This material is carbon if the carbonization develops sufficiently. A portion not carbonized in single-crystal group 10 is still made of silicon carbide. The portion will be referred to as “silicon carbide portion 90”. Then, first protective film 71 and second protective film 72 are removed by, for example, grinding or polishing.

Referring to FIG. 21, by the above-described step, single-crystal group 10 is divided into carbonized portion 70 and silicon carbide portion 90. Further, second surface B0 thereof is divided into the following portions: a portion constituted by silicon carbide portion 90 and having a shape corresponding to the planar shape of base portion 30; and a portion constituted by carbonized portion 70 and exposed outside the portion constituted by silicon carbide portion 90.

Referring to FIG. 22, as a result of the carbonization, an interface IE is formed between carbonized portion 70 and silicon carbide portion 90, so as to extend from second surface B0 to come into single-crystal group 10 in the direction in which the carbonization has developed, i.e., substantially the direction of thickness (vertical direction in FIG. 22).

Then, in order to facilitate separation along interface IE, stress is applied to single-crystal group 10. For example, force FC is applied to push carbonized portion 70 on second surface B0 while the portion of second surface B0 constituted by silicon carbide portion 90 in single-crystal group 10 (portion on the left side in FIG. 22) is fixed. This force FC causes stress in single-crystal group 10, which results in separation along interface IE from a location on second surface B0. In other words, a process is performed to separate carbonized portion 70 along its interface.

This separation causes a crack along interface IE. The crack develops to come into silicon carbide portion 90, and finally reaches first surface F0. In other words, the crack develops as indicated by a broken line arrow CR (FIG. 22). As a result, when viewed in a planar view, the portion provided with carbonized portion 70 (portion located at the right side with respect to broken line arrow CR in FIG. 22) in single-crystal group 10 is removed, while the other portion remains. This remaining portion has a shape corresponding to that of base portion 30 (FIG. 17) when viewed in a planar view, i.e., a shape corresponding to that of silicon carbide substrate 80 (FIG. 15). Namely, by the steps described above, single-crystal group 10 (FIG. 17: collection of single-crystals 11-19) is provided with a planar shape corresponding to that of silicon carbide substrate 80. Single-crystal group 10 thus provided with the planar shape are likely to have a rough side surface because the side surface is formed as a result of the development of the crack. Hence, the side surface may be cut, ground, or polished as required. In this way, silicon carbide substrate 80 is obtained.

According to the present embodiment, the following processes are performed as the process for removing the portion of single-crystal group 10 (portion located at the right side with respect to broken line arrow CR in FIG. 22) in order to adjust the planar shape of single-crystal group 10: the process on interface IE of carbonized portion 70 as indicated by broken line arrow CR (FIG. 22); and the process on the inside of silicon carbide portion 90. The former process, i.e., the process for separation along interface IE, can be readily performed as compared with a process on silicon carbide, which has a high hardness. Thus, a part of the process of adjusting the planar shape of single-crystal group 10 can be done more readily. Accordingly, silicon carbide substrate 80 having a desired planar shape can be obtained readily.

Further, single-crystal group 10 includes the plurality of single-crystals 11-19 arranged at different locations, when viewed in a planar view. Accordingly, the area of the single-crystal substrate can be larger than that in a case of using only one single-crystal.

Further, upon the carbonization of single-crystal group 10, base portion 30 serves as a mask partially covering second surface B0 of single-crystal group 10, whereby only the portion of second surface B0 can be carbonized. Furthermore, because base portion 30 is made of silicon carbide, base portion 30 is suitable to constitute a portion of silicon carbide substrate 80.

The separation along interface IE (FIG. 22) can be done only by such a simple method as application of stress onto interface IE in single-crystal group 10. Further, the crack resulting from the separation develops to come into silicon carbide portion 90. In this way, a process of forming a crack at a desired location in silicon carbide portion 90 can be attained.

Further, carbonized portion 70 (FIG. 20) can be formed by a simple method such as heating of single-crystal group 10. When temperature in the atmosphere upon the heating is set at 1800° C. or greater, the carbonization is done more securely. In addition, when the temperature is set at 2500° C. or smaller, single-crystal group 10 can be less damaged by the heating. By heating with the atmosphere being evacuated, silicon atoms desorbed from single-crystal group 10 are removed from the atmosphere, thereby facilitating desorption of silicon atoms from single-crystal group 10 to the atmosphere. In other words, development of carbonization is facilitated, thereby efficiently manufacturing silicon carbide substrate 80.

Further, first protective film 71 (FIG. 20) serves to prevent carbonization of first surface F0. Preferably, first protective film 71 is made of a material containing carbon as its main component. This material may contain at least one of diamondlike carbon, carbon, a material obtained by carbonization of a resist, and a material obtained by carbonization of silicon carbide. Accordingly, first protective film 71 becomes a film stable even under a high temperature, thereby preventing carbonization of first surface F0 more securely. Note that it is not essential to form first protective film 71. In the case where first protective film 71 is not formed, first surface F0 is carbonized up to a certain depth upon forming carbonized portion 70, but the portion carbonized in first surface F0 can be removed by, for example, grinding or polishing.

Meanwhile, second protective film 72 (FIG. 20) serves to prevent carbonization of second main surface Q2. Note that it is not essential to form second protective film 72. In the case where second protective film 72 is not formed, second main surface Q2 is carbonized up to a certain depth upon forming carbonized portion 70, but the portion carbonized in second main surface Q2 can be removed by, for example, grinding or polishing, as required.

In the present embodiment, single-crystal group 10 is constituted by the plurality of single-crystals. However, if the area of the silicon carbide substrate does not need to be large by using the plurality of single-crystals, one single-crystal may be used instead of the single-crystal group.

Further, the shape of the base portion is not limited to the circular shape, and may be any shape corresponding to the planar shape of the silicon carbide substrate.

### Fifth Embodiment

A silicon carbide substrate of the present embodiment has a configuration substantially the same as that in the fourth embodiment (FIG. 15 and FIG. 16). Further, early steps in a method for manufacturing the silicon carbide substrate of the present embodiment are the same as those in the method for manufacturing in the fourth embodiment (steps for obtaining the configuration of FIG. 21). The same or corresponding elements as those in the fourth embodiment are given the same reference characters and are not described repeatedly. The following describes later steps in the manufacturing method in the present embodiment.

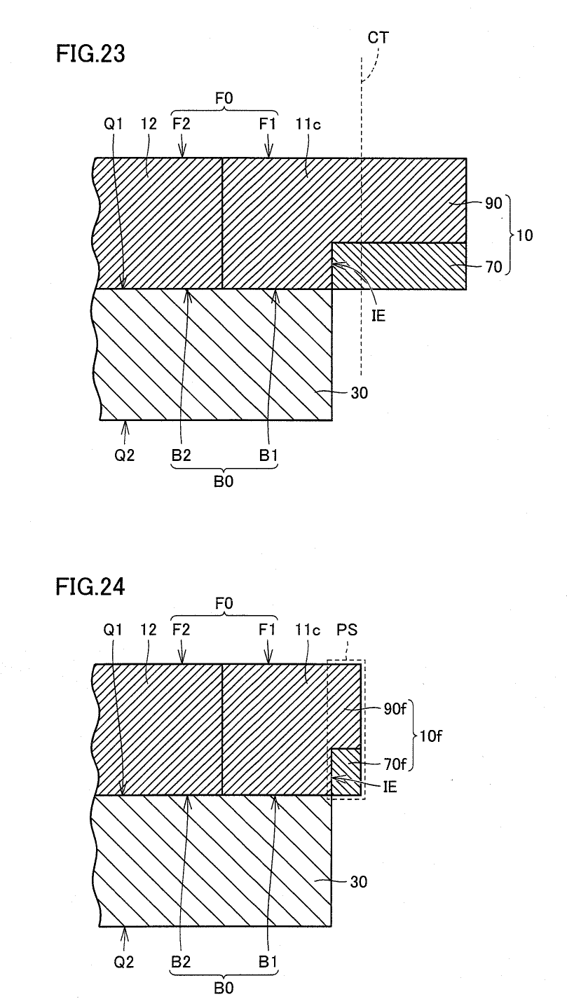

Referring to FIG. 23 mainly, as indicated by a broken line CT (FIG. 23), carbonized portion 70 and silicon carbide portion 90 are cut off, thereby removing most of the portion in which carbonized portion 70 is formed when viewed in a planar view (portion located at the outer side with respect to the broken line in FIG. 8). This cutting-off is done by, for example, at least one of a machining process such as grinding or polishing, a laser process, and an electric discharge process.

Further, referring to FIG. 24, most of carbonized portion 70 (FIG. 23) is removed by the cutting-off, although there is a remaining portion of carbonized portion 70, i.e., a carbonized portion 70f (FIG. 24). Then, a portion in which carbonized portion 70f exists when viewed in a planar view, i.e., a portion PS (FIG. 24) having carbonized portion 70f and a silicon carbide portion 90f is removed by, for example, cutting, grinding, or polishing. Accordingly, silicon carbide substrate 80 (FIG. 15 and FIG. 16) is obtained.

According to the present embodiment, as shown in FIG. 23, a part of the process of cutting off single-crystal group 10 represents the process of cutting off carbonized portion 70. Specifically, in the part of the process of cutting off single-crystal group 10, the material obtained by carbonizing silicon carbide, rather than silicon carbide, is cut off. Such a process can be readily performed as compared with a process of cutting off silicon carbide. As such, the part of the process of cutting off single-crystal group 10 can be performed more readily. Accordingly, silicon carbide substrate 80 having a desired planar shape can be obtained readily.

### Sixth Embodiment

A silicon carbide substrate of the present embodiment has a configuration substantially the same as that in the fourth embodiment (FIG. 15 and FIG. 16). Further, early steps in a method for manufacturing the silicon carbide substrate of the present embodiment are the same as those in the method for manufacturing in the fourth embodiment (steps for obtaining the configuration of FIG. 20). The same or corresponding elements as those in the fourth embodiment are given the same reference characters and are not described repeatedly. The following describes later steps in the manufacturing method in the present embodiment.

Referring to FIG. 20, the carbonizing step is performed in a manner similar to that in the fourth embodiment, thereby forming carbonized portion 70. In the present embodiment, the carbonization is developed further.

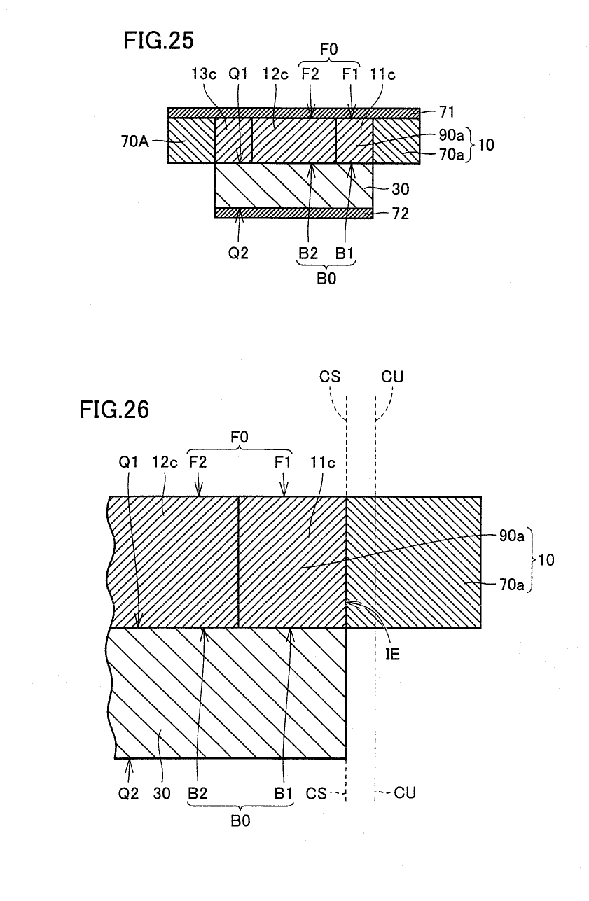

Referring to FIG. 25, by the above-described step, single-crystal group 10 is divided into a carbonized portion 70a and a silicon carbide portion 90a. Carbonized portion 70a is formed to extend from second surface B0 to first surface F0.

Referring to FIG. 26, as indicated by a broken line CS in the figure, separation is done along interface IE between carbonized portion 70a and silicon carbide portion 90a. This separation is attained by applying stress in the same manner as in the fourth embodiment. As a result of this separation, carbonized portion 70a is removed. Thereafter, the side surface of 90a (surface used to be interface IE) may be cut, ground, or polished. Accordingly, silicon carbide substrate 80 (FIG. 15 and FIG. 16) is obtained.

Instead of the separation along broken line CS (FIG. 26), it may be cut along a broken line CU (FIG. 26). This cutting may be performed using a method similar to that in the fifth embodiment. A remaining portion of carbonized portion 70a (portion between broken line CU and interface IE in FIG. 26) is removed by, for example, cutting, grinding, or polishing.

Further, first protective film 71 (FIG. 19) may be formed into a planar shape similar to that of base portion 30. In this way, carbonization for formation of carbonized portion 70a (FIG. 25) develops not only from second surface B0 but also from first surface F0, thereby forming carbonized portion 70a more efficiently.

### Seventh Embodiment

In the present embodiment, the following particularly describes one embodiment of the method for manufacturing combined substrate 89 (FIG. 17 and FIG. 18), in detail. In fabricating silicon carbide substrate 80 (FIG. 15 and FIG. 16) from combined substrate 89, any of the methods described in the forth to sixth embodiments may be employed. The same or corresponding elements as those in the fourth to sixth embodiments are given the same reference characters and are not described repeatedly. The following describes later steps in the manufacturing method in the present embodiment.

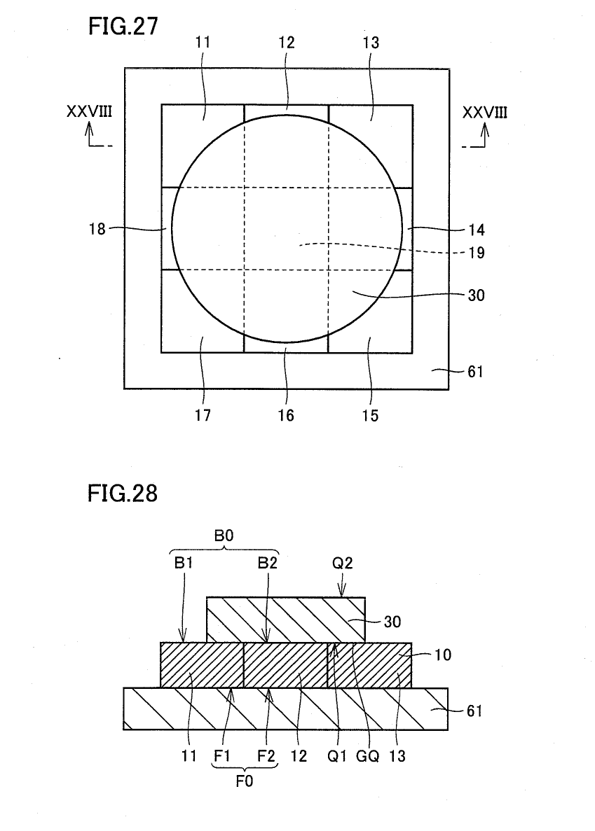

Referring to FIG. 27 and FIG. 28, a first heating member 61 is prepared. First heating member 61 has a function of absorbing heat emitted from a below-described heater and emitting the absorbed heat so as heat base portion 30 and single-crystal group 10. First heating member 61 is formed of, for example, graphite with a small porosity.

On first heating member 61, single-crystals 11-19, i.e., single-crystal group 10 are arranged in the form of a matrix. Next, base portion 30 is placed on single-crystal group 10. At this point of time, base portion 30 is merely placed on single-crystal group 10, and is not connected thereto. Hence, when viewed microscopically, there is a gap GQ therebetween. Gap GQ has an average height (dimension in the vertical direction in FIG. 28) of, for example, several ten p.m. This value depends on surface roughness and warpage of each of single-crystal group 10 and base portion 30.

Also, at this point of time, base portion 30 may have any of single-crystal, polycrystal, and amorphous structures. Preferably, base portion 30 has a crystal structure similar to that of single-crystal group 10, but base portion 30 may have a defect density higher than that of single-crystal group 10. Hence, a large base portion 30 can be relatively readily prepared.

Further, the planar shape of base portion 30 corresponds to the planar shape of silicon carbide substrate 80. In the present embodiment, the planar shape of base portion 30 is a circular shape. The diameter of the circular shape is preferably 5 cm or greater, more preferably 15 cm or greater in order to obtain silicon carbide substrate 80 having a large diameter.

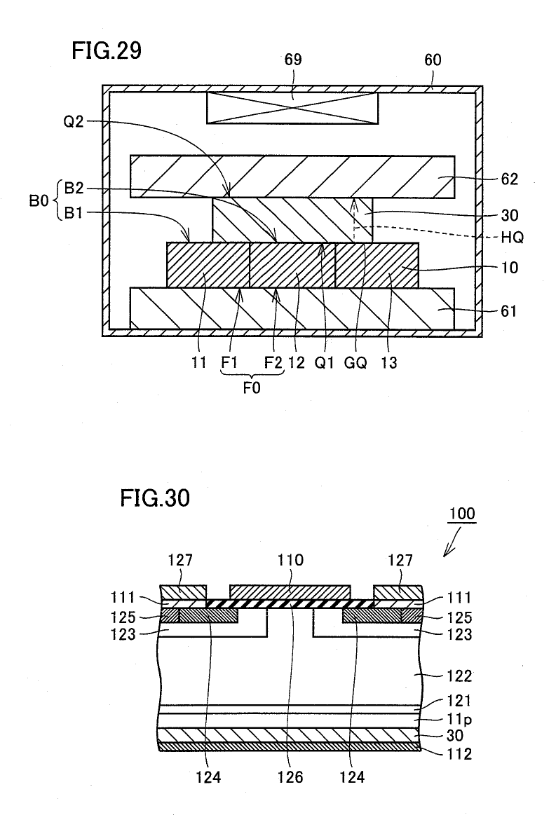

Referring to FIG. 29, a second heating member 62 is placed on base portion 30. Second heating member 62 has a function similar to that of first heating member 61. Next, the stacked structure of first heating member 61, single-crystal group 10, base portion 30, and second heating member 62 is contained in a container 60. Container 60 preferably has a high heat resistance and is made of graphite, for example.

Then, base portion 30 and single-crystal group 10 are heated to allow a temperature of base portion 30 to reach a sublimation temperature of silicon carbide, and allow a temperature of single-crystal group 10 to be lower than the temperature of base portion 30. Such heating can be accomplished by providing a temperature gradient such that the temperature of single-crystal group 10 becomes lower than the temperature of base portion 30 in container 60. Such a temperature gradient can be provided by, for example, disposing a heater 69 at a location closer to second heating member 62 relative to first heating member 61. This heating results in sublimation of silicon carbide from first main surface Q1 of base portion 30. Then, the silicon carbide thus sublimated is recrystallized on second surface B0 of single-crystal group 10. This connects second surface B0 of single-crystal group 10 and first main surface Q1 of base portion 30 to each other. The following describes this heating step in detail.

First, atmosphere in container 60 is exhausted. Preferably, the exhaustion is continuously performed to allow pressure in container 60 to be preferably 50 kPa or smaller, more preferably, 10 kPa or smaller.

Next, single-crystal group 10 and base portion 30 are heated. They are heated to bring at least the temperature of base portion 30 to a temperature equal to or higher than the sublimation temperature of silicon carbide. Specifically, a setting temperature for heater 69 is not less than 1800° C. and not more than 2500° C. For example, the setting temperature is 2000° C. When the temperature is 1800° C. or smaller, the heating is likely to be insufficient for sublimation of silicon carbide. On the other hand, when the temperature is 2500° C. or greater, the surface of single-crystal group 10 is likely to be notably rough. Further, this heating is performed to form a temperature gradient such that the temperature is decreased from base portion 30 to single-crystal group 10 in container 60. The temperature gradient is preferably not less than 1° C./cm and not more than 200° C./cm, more preferably, not less than 10° C./cm and not more than 50° C./cm.

With the temperature gradient thus provided, there occurs a temperature difference between second surface B0 of single-crystal group 10 and first main surface Q1 of base portion 30. This temperature difference is obtained more surely due to the existence of gap GQ. Due to this temperature difference, sublimation reaction of silicon carbide is more likely to take place from base portion 30 into gap GQ as compared with that from single-crystal group 10. On the other hand, recrystallization reaction resulting from the supply of the silicon carbide material from gap GQ is more likely to take place on single-crystal group 10 as compared with that on base portion 30. As a result, as indicated by a broken line arrow HQ (FIG. 29), gap GQ is transferred due to the sublimation/recrystallization reaction. More specifically, gap GQ is first divided into a multiplicity of voids in base portion 30. Then, these voids may be transferred in a direction indicated by broken line arrow HQ to eliminate them from base portion 30.

By the sublimation/recrystallization reactions, the entire base portion 30 or a part of base portion 30 is epitaxially formed into a layer on second surface B0 of single-crystal group 10. As a result, base portion 30 is connected to single-crystal group 10 so as to partially cover second surface B0 of single-crystal group 10. Further, the entire crystal structure or a part of the crystal structure of base portion 30 is changed from its initial structure into a structure corresponding to the crystal structure of single-crystal group 10. Accordingly, combined substrate 89 (FIG. 17 and FIG. 18) is obtained.

### Eighth Embodiment

In the present embodiment, the following describes a semiconductor device employing silicon carbide substrate 80 (FIG. 15 and FIG. 16). Silicon carbide substrate 80 can be prepared in accordance with any of the foregoing fourth to seventh embodiments. The same or corresponding elements as those in the fourth to seventh embodiments are given the same reference characters and are not described repeatedly.

Referring to FIG. 30, a semiconductor device 100 of the present embodiment is a DiMOSFET (Double Implanted Metal Oxide Semiconductor Field Effect Transistor) of vertical type, and has base portion 30, single-crystal lip, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112. Semiconductor device 100 has a planar shape (shape when viewed from upward in FIG. 30) of, for example, a rectangle or a square with sides each having a length of 2 mm or greater.

Drain electrode 112 is provided on base portion 30 and buffer layer 121 is provided on single-crystal 11p. With this arrangement, a region in which flow of carriers is controlled by gate electrode 110 is disposed not in base portion 30 but in single-crystal 11p.

Each of base portion 30, single-crystal lip, and buffer layer 121 has n type conductivity. Impurity with n type conductivity in buffer layer 121 has a concentration of, for example, 5×10¹⁷ cm⁻³. Further, buffer layer 121 has a thickness of for example, 0.5 μm.

Reverse breakdown voltage holding layer 122 is formed on buffer layer 121, and is made of SiC with n type conductivity. For example, reverse breakdown voltage holding layer 122 has a thickness of 10 μm, and includes a conductive impurity of n type at a concentration of 5×10¹⁵ cm⁻³.

Reverse breakdown voltage holding layer 122 has a surface in which the plurality of p regions 123 of p type conductivity are formed with spaces therebetween. In each of p regions 123, an n⁺ region 124 is formed at the surface layer of p region 123. Further, at a location adjacent to n⁺ region 124, a p⁺ region 125 is formed. Oxide film 126 is formed on reverse breakdown voltage holding layer 122 exposed between the plurality of p regions 123. Oxide film 126 is formed to extend on n⁺ region 124 in one p region 123, p region 123, an exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed.

The maximum value of nitrogen atom concentration is 1×10²¹ cm⁻³ or greater in a region distant away by 10 nm or shorter from an interface between oxide film 126 and each of the semiconductor layers, i.e., n⁺ regions 124, p⁺ regions 125, p regions 123, and reverse breakdown voltage holding layer 122. This achieves improved mobility particularly in a channel region below oxide film 126 (a contact portion of each p region 123 with oxide film 126 between each of n⁺ regions 124 and reverse breakdown voltage holding layer 122).

Illustrated in the description above is the semiconductor device including single-crystal 11p, but a semiconductor devices including another single-crystal instead of single-crystal 11p (any one of single-crystals 12p-18p and 19 in FIG. 15) is also obtained at the same time by the method for manufacturing semiconductor devices using silicon carbide substrate 80.

The following describes a method for manufacturing a semiconductor device 100. It should be noted that FIG. 32-FIG. 36 show steps only in the vicinity of single-crystal 11p, but the same steps are performed also in the vicinity of each of single-crystals 12p-18p and 19.

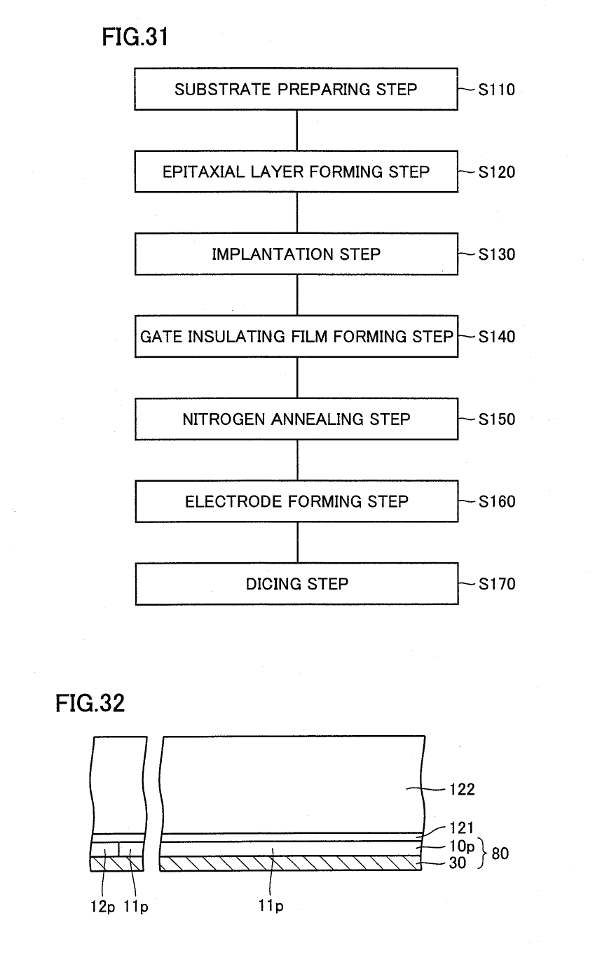

First, in a substrate preparing step (step S110: FIG. 31), silicon carbide substrate 80 (FIG. 15 and FIG. 16) is prepared. Silicon carbide substrate 80 can be manufactured using, for example, any of the methods of the fourth to sixth embodiments. Silicon carbide substrate 80 has n type conductivity.

Referring to FIG. 32, in an epitaxial layer forming step (step S120: FIG. 31), buffer layer 121 and reverse breakdown voltage holding layer 122 are formed as follows.

First, buffer layer 121 is formed on a surface of single-crystal group 10p. Buffer layer 121 is made of SiC of n type conductivity, and is an epitaxial layer having a thickness of 0.5 μm, for example. Buffer layer 121 has a conductive impurity at a concentration of, for example, 5×10¹⁷ cm⁻³.

Next, reverse breakdown voltage holding layer 122 is formed on buffer layer 121. Specifically, a layer made of SiC of n type conductivity is formed using an epitaxial growth method. Reverse breakdown voltage holding layer 122 has a thickness of for example, 10 μm. Further, reverse breakdown voltage holding layer 122 includes an impurity of n type conductivity at a concentration of, for example, 5×10¹⁵ cm⁻³.

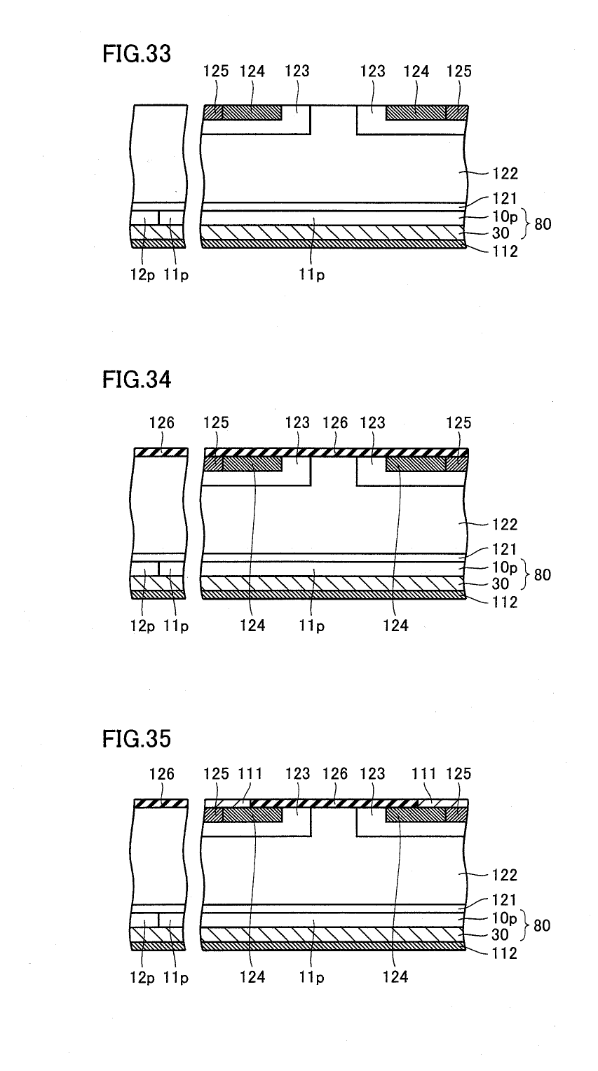

Referring to FIG. 33, an implantation step (step S130: FIG. 31) is performed to form p regions 123, n⁺ regions 124, and p⁺ regions 125 as follows.

First, a conductive impurity of p type conductivity is selectively implanted into portions of reverse breakdown voltage holding layer 122, thereby forming p regions 123. Then, a conductive impurity of n type is selectively implanted to predetermined regions to form n⁺ regions 124, and a conductive impurity of p type is selectively implanted into predetermined regions to form p⁺ regions 125. It should be noted that such selective implantation of the impurities is performed using a mask formed of, for example, an oxide film.

After such an implantation step, an activation annealing process is performed. For example, the annealing is performed in argon atmosphere at a heating temperature of 1700° C. for 30 minutes.

Referring to FIG. 34, a gate insulating film forming step (step S140: FIG. 31) is performed. Specifically, oxide film 126 is formed to cover reverse breakdown voltage holding layer 122, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitrogen annealing step (step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

Referring to FIG. 35, an electrode forming step (step S160: FIG. 31) is performed to form source electrodes 111 and drain electrode 112 in the following manner.

First, a resist film having a pattern is formed on oxide film 126, using a photolithography method. Using the resist film as a mask, portions above n⁺ regions 124 and p⁺ regions 125 in oxide film 126 are removed by etching. In this way, openings are formed in oxide film 126. Next, in each of the openings, a conductive film is formed in contact with each of n⁺ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

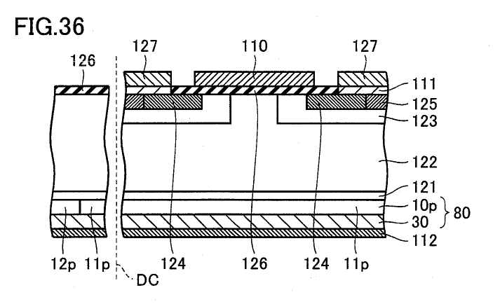

Referring to FIG. 36 again, upper source electrodes 127 are formed on source electrodes 111. Further, gate electrode 110 is formed on oxide film 126. Further, drain electrode 112 is formed on the backside surface of silicon carbide substrate 80.

Next, in a dicing step (step S170: FIG. 31), dicing is performed as indicated by a broken line DC. Accordingly, a plurality of semiconductor devices 100 (FIG. 30) are obtained by the cutting.

It should be noted that a configuration may be employed in which conductive types are opposite to those in the present embodiment. Namely, a configuration may be employed in which p type and n type are replaced with each other. Further, the DiMOSFET of vertical type has been exemplified, but another semiconductor device may be manufactured using the semiconductor substrate of the present invention. For example, a RESURF-JFET (Reduced Surface Field-Junction Field Effect Transistor) or a Schottky diode may be manufactured.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing a material substrate having a first surface and a second surface opposite to each other in a thickness direction and made of silicon carbide;
partially carbonizing said material substrate so as to divide said material substrate into a carbonized portion and a silicon carbide portion, said carbonized portion being made of a material obtained by carbonizing silicon carbide, said silicon carbide portion being made of silicon carbide, the step of carbonizing being performed to partially carbonize said second surface; and
removing a portion of said material substrate so as to adjust a shape of said material substrate when viewed in a planar view, the step of removing including the step of processing said carbonized portion.

2. The method for manufacturing the silicon carbide substrate according to claim 1, wherein the step of removing includes the step of applying stress to said material substrate.

3. The method for manufacturing the silicon carbide substrate according to claim 2, wherein the step of processing said carbonized portion is performed by separating said carbonized portion from its interface with said silicon carbide portion by said stress.

4. The method for manufacturing the silicon carbide substrate according to claim 3, wherein the step of removing includes the step of developing a crack, which is caused by said separating, to come into said silicon carbide portion.

5. The method for manufacturing the silicon carbide substrate according to claim 1, wherein the step of processing said carbonized portion includes the step of cutting off said carbonized portion by means of at least one of a machining process, a laser process, and an electric discharge process.

6. The method for manufacturing the silicon carbide substrate according to claim 1, wherein the step of carbonizing includes the step of heating said material substrate to partially carbonize said material substrate.

7. The method for manufacturing the silicon carbide substrate according to claim 6, wherein the step of heating includes the step of subjecting said material substrate to an atmosphere having a temperature of not less than 1800° C. and not more than 2500° C.

8. The method for manufacturing the silicon carbide substrate according to claim 6, wherein the step of carbonizing includes the step of evacuating an atmosphere surrounding said material substrate.

9. The method for manufacturing the silicon carbide substrate according to claim 1, further comprising the step of forming a first protective film on said first surface before the step of carbonizing.

10. The method for manufacturing the silicon carbide substrate according to claim 9, wherein said first protective film is made of a first material containing carbon as its main component.

11. The method for manufacturing the silicon carbide substrate according to claim 10, wherein said first material contains at least one of diamondlike carbon, carbon, a material obtained by carbonizing a resist, and a material obtained by carbonizing silicon carbide.

12. The method for manufacturing the silicon carbide substrate according to claim 1, further comprising the step of forming, before the step of carbonizing, a base portion connected to and partially covering said second surface of said material substrate and made of silicon carbide.

13. The method for manufacturing the silicon carbide substrate according to claim 12, further comprising the step of forming, before the step of carbonizing, a second protective film on said base portion.

14. The method for manufacturing the silicon carbide substrate according to claim 12, wherein said material substrate includes at least one single-crystal.

15. The method for manufacturing the silicon carbide substrate according to claim 14, wherein said at least one single-crystal includes a plurality of single-crystals located at different locations when viewed in a planar view.
